(19) United States
(12) Patent Application Publication
(10) Pub. No.: US 2014/0187716 A1
(43) Pub. Date: Jul. 3, 2014

(54) PROCESS FOR THE SYNTHESIS OF CONJUGATED POLYMERS

(71) Applicants: David John Jones, Melbourne (AU); Wing Ho Wallace Wong, Melbourne (AU); Andrew Bruce Holmes, Melboune (AU); Helga Seyler, Melbourne (AU)

(72) Inventors: David John Jones, Melbourne (AU); Wing Ho Wallace Wong, Melbourne (AU); Andrew Bruce Holmes, Melboune (AU); Helga Seyler, Melbourne (AU)

(73) Assignee: The University of Melbourne, Melbourne, Victoria (AU)

(21) Appl. No.: 14/232,132

(22) PCT Filed: Jul. 13, 2012
(86) PCT No.: PCT/AU2012/000837

§ 371 Date: Feb. 5, 2014

(30) Foreign Application Priority Data
Jul. 15, 2011 (AU) 2011902817

(51) Int. Cl. C08G 61/12; C08G 61/02; H01L 51/00; C08G 61/10

(52) U.S. Cl. CPC C08G 61/126; C08G 61/10; C08G 61/025; H01L 51/0039; H01L 51/0036; H01L 51/0038
USPC 525/55; 528/8; 528/7; 526/240; 528/212; 526/75; 526/90; 526/64; 525/389; 525/390

(57) ABSTRACT

Processes for the continuous production of conjugated polymers are disclosed. The processes provide excellent control over reaction parameters and are highly reproducible. The conjugated polymers find use in heterojunction devices.

### FIELD OF THE INVENTION

Continuous processes for the synthesis of conjugated polymers are disclosed. Such conjugated polymers find particular, although not exclusive, use as organic semiconductor materials.

### BACKGROUND TO THE INVENTION

Since the first studies on the conductive properties of doped polyacetylene by Heeger, MacDiarmid, and Shirakawa more than three decades ago, [Chiang, C. K.; Druy, M. A.; Gau, S. C.; Heeger, A. J.; Louis, E. J.; MacDiarmid, A. G.; Park, Y. W.; Shirakawa, H. J. Am. Chem. Soc. 1978, 100, 1013-1015] conjugated polymers have developed into one of the most important class of organic compounds in materials science. Conjugated polymers can now be used as the active layer in a wide range of devices spanning applications from conducting materials in anti-static films and electrodes to semi-conducting applications in light emitting diodes (LED), field effect transistors (FET) and photovoltaics (PV). This is a result of the highly tunable photophysical and optoelectronic properties of the polymers through molecular structure manipulations. In addition, with the prospect of low-cost flexible electronic devices, the solution processability and flexibility of polymers make these materials particularly attractive for roll-to-roll device manufacture. In order to optimise the performance of printed devices, time must be invested in printing trials which will consume large quantities of materials. This requires cost-effective methods of production of materials at scale.

Continuous synthesis methods offer the possibility of production of materials in a safe, reproducible and scalable manner, [Jas, G.; Kirschning, A. Chem. Eur. J. 2003, 9, 5708-5723]. Continuous synthesis methods are often applied in industrial processes and a number of research groups have studied reactions on laboratory scale equipment such as microfluidic chips and tubular reactors, [Jähnisch, K.; Hessel, V.; Löwe, H.; Baerns, M. Angew. Chem. Int. Ed. 2004, 43, 406-446; Geyer, K.; Codee, J. D. C.; Seeberger, P. H. Chem. Eur. J. 2006, 12, 8434-8442; Razzaq, T.; Kappe, C. O. Chem. Asian J. 2010, 5, 1274-1289; Chemical Reactions and Processes under Flow Conditions; Luis, S. V.; Garcia-Verdugo, E., Eds.; RSC Publishing: London, 2010].

It would be desirable to provide improved methods for the synthesis of conjugated polymers.

### SUMMARY OF THE EMBODIMENTS

According to a first aspect there is provided a continuous process for the synthesis of conjugated polymers wherein the continuous process comprises one or more process steps.

The present inventors have surprisingly found that conjugated polymers may be rapidly and efficiently produced under continuous process conditions. Advantages of the continuous processes may include, scalability and a significant reduction in reaction time in comparison to traditional processes based on batch reactions. Further advantages may include, superior heat transfer, improved reagent stoichiometry control, a closed and fully contained reactor system allowing for safe handling of hazardous reagents and high pressure reactions, and excellent reproducibility owing to precise control of parameters, such as reaction time, temperature and pressure.

In some embodiments conjugated polymers having desirable molecular mass distribution may be produced in a rapid and reproducible manner.

It will be understood that the term process step applies equally to a process step involved in the synthesis of monomers and to a process step involved in the synthesis of polymers.

Accordingly, in some embodiments, the continuous process comprises one or more monomer synthesis steps followed by one or more polymer synthesis steps.

It will be appreciated by the skilled artisan, that the ability to integrate monomer and polymer synthesis through suitably linked continuous process steps offers many possible advantages to traditional batch processes.

In some embodiments monomers may be continuously synthesised by one or more process steps selected from the group consisting of selective halogenation, lithiation, metallation/transmetallation, borylation, formylation, alkylation or combinations thereof. These can be realised with surprising selectivity, for example, regioselective monofunctionalization of an aromatic/heteroaromatic molecule through replacement of Ar—H or HetAr—H by M, where M=Li, Mg, by use of a reactive organometallic base, mono-metallation, mono-borylation, mono-formylation, mono-silylation, mono-stannylation or mono-alkylation of a symmetrically substituted dihalo-aromatic/heteraromatic substrate. In metallation reactions, the metal may be selected from: Li(I), Cu(I/II), Mg(II), Zn(II), which may be used as precursors for carbon bond forming reactions.

In some embodiments conjugated polymers may be continuously synthesised by one or more process steps selected from the group consisting of palladium-catalysed polycondensations such as Suzuki, Stille, Sonogashira and Heck reactions, Buchwald-Hartwig amination, ring opening metathesis polymerisation, Yamamoto polycondensation, Gilch polymerisation, Wittig polycondensations, Grignard metathesis polymerisations or combinations thereof.

Exemplary, but non-limiting conjugated polymers which may be continuously synthesized by the present processes may be selected from the group consisting of poly(fluorene), poly(dibenzosilole), poly(dibenzogermole), poly(dibenzophosphole oxide), poly(phenylene), poly(pyrene), poly(azulene), poly(naphthalene), poly(pyrole), poly(carbazole), poly(indole), poly(azepine), poly(aniline), poly(thiophene), poly(3,4-ethylenedioxythiophene), poly(cyclopentadithiophene), poly(dithienosilole), poly(dithienogermole), poly(dithienophosphole oxide), poly(benzodithiophene), poly(benzotriazole), poly(thiazole), poly(p-phenylene sulphide), poly(acetylene) and poly(p-phenylenevinylene).

In some embodiments the processes may be automated using process control systems, for example, through control of pressure and/or temperature. This is advantageous in respect of the selective installation of functional groups on monomeric materials and in obtaining polymeric materials in a reproducible manner.

The synthesis of monomers and/or the polymerisations may be carried out in a single solvent, in mixtures of solvents or under monophasic or biphasic conditions. Where catalysts are used in the processes they may be homogeneous and/or heterogeneous. In some embodiments the reacting components, such as monomer and/or monomer precursors may be stored separately from, for example, catalysts and/or other reagents and the various components mixed either prior to entry into the continuous reactor or alternatively and/or additionally added as separate streams to the continuous reactor.

The continuous processes may comprise a single reaction step or multiple reaction steps. In the latter case, different temperatures or other conditions, such as irradiation, may be applied at individual process sections to promote or accelerate intermediate steps.

In some embodiments, one or more further reactors may be utilised to perform one or more further processing steps on the conjugated polymers. For example in-line end-capping and/or chain extension to produce block polymers. The block polymers may be block copolymers.

The continuous processes may be performed in one or more tubular reactors or one or more continuous stirred tank reactors or combinations of both. The reactors may be arranged in series or in parallel depending on the specific nature of the chemical steps and the target product mix.

Where heterogeneous components are utilised these may be advantageously present in the reactor in the form of one or more fixed beds, for example a fixed bed heterogeneous catalyst.

According to a third aspect there is provided a conjugated polymer prepared by the process according to any one of the aforementioned aspects.

In some embodiments the conjugated polymer comprises one or more monomer units which have been synthesised in a continuous process.

Exemplary conjugated polymers include poly(fluorene), poly(dibenzosilole), poly(dibenzogermole), poly(dibenzophosphole oxide), poly(phenylene), poly(pyrene), poly(azulene), poly(naphthalene), poly(pyrole), poly(carbazole), poly(indole), poly(azepine), poly(aniline), poly(thiophene), poly(3,4-ethylenedioxythiophene), poly(cyclopentadithiophene), poly(dithienosilole), poly(dithienogermole), poly(dithienophosphole oxide), poly(benzodithiophene), poly(benzotriazole), poly(thiazole), poly(p-phenylene sulphide), poly(acetylene) and poly(p-phenylenevinylene).

According to a fourth aspect there is provided a use of the conjugated polymer prepared by the process according to any one of the aforementioned aspects in a hetero-junction device.

According to a fifth aspect there is provided a hetero-junction device comprising one or more conjugated polymers prepared by the process according to any one of the aforementioned aspects.

Throughout this specification, use of the terms “comprises” or “comprising” or grammatical variations thereon shall be taken to specify the presence of stated features, integers, steps or components but does not preclude the presence or addition of one or more other features, integers, steps, components or groups thereof not specifically mentioned.

### BRIEF DESCRIPTION OF THE FIGURES

The present invention will now be described with reference to the accompanying Figures where:

FIG. 1 illustrates a scheme for polymer synthesis via Suzuki polycondensation.

FIG. 2 illustrates a scheme for continuous production of PTB via Stille polycondensation.

FIG. 3 illustrates a scheme for continuous production of MEH-PPV.

FIG. 4 illustrates a scheme for continuous Grignard metathesis.

### DETAILED DESCRIPTION OF THE EMBODIMENTS

It will now be convenient to describe the invention with reference to particular embodiments and examples. These embodiments and examples are illustrative only and should not be construed as limiting upon the scope of the invention. It will be understood that variations upon the described invention as would be apparent to the skilled artisan are within the scope of the invention. Similarly, the present invention is capable of finding application in areas that are not explicitly recited in this document and the fact that some applications are not specifically described should not be considered as a limitation on the overall applicability of the invention.

General Conditions

The process reaction conditions may be appropriately varied and are dependent on the nature of the chemical reaction in question. Reaction pressures may range from 40 to 600 psi. Preferably reaction pressures are below 250 psi. The reactor residence time may vary, again depending on the specific chemistry, reagent stoichiometry and temperature. Residence times may be in the range of 0.1 and 10 hours, preferably in the range of 0.25 to 4 hours, more preferably in the range of 0.5 to 2 hours.

### Suzuki Polycondensation for the Synthesis of poly(9,9-dioctylfluorene)

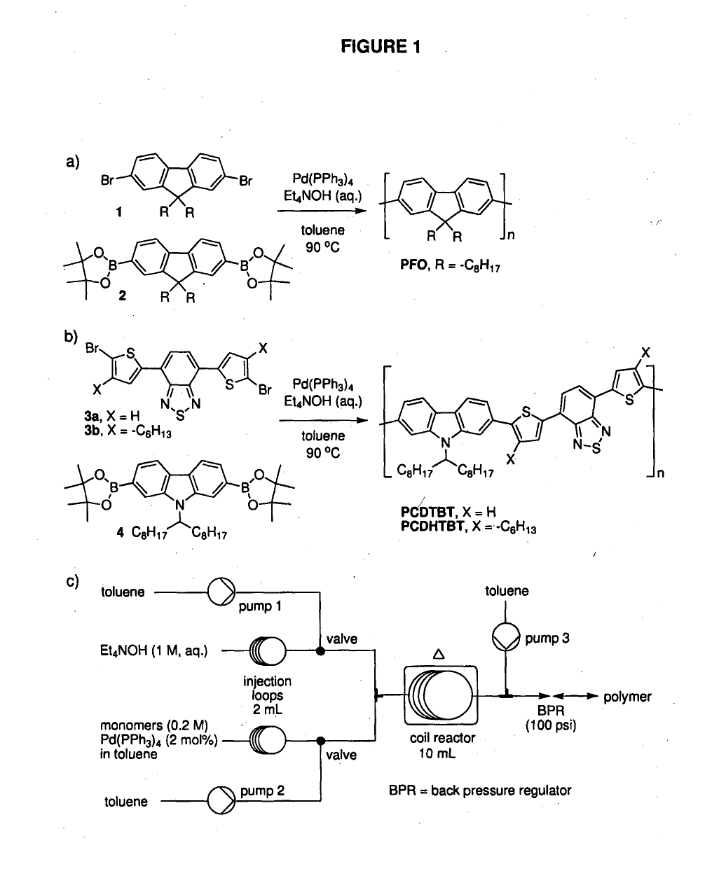

One of the most common methods for the synthesis of solution processable conjugated polymers is Suzuki polycondensation. Typically, dibromo aryl monomer units and aryl bis-boronic acid derivatives are coupled together using a palladium catalyst in the presence of base and suitable organic solvent. With readily available starting materials, poly(9,9-dioctylfluorene) PFO was chosen as a model system for initial test reactions. PFO has a characteristic blue emission and is used in OLED devices [Grimsdale, A. C.; Chan, K. L.; Martin, R. E.; Jokisz, P. G.; Holmes, A. B. Chem. Rev. 2009, 109, 897-10911 It has been synthesized using a variety of methods, with Suzuki polycondensation being the most common. The use of toluene and an aqueous solution of tetraethylammonium hydroxide (Et₄NOH) with tetrakis(triphenylphopshine)-palladium(0), Pd(PPh₃)₄, as catalyst gives the good results in standard batch polymerisations (FIG. 1; Scheme a). Under these conditions, all reactants, reagents and products are kept in solution throughout the reaction. This is an important consideration for translation of the reaction to a continuous reactor.

The continuous reactions were performed using a commercially available reactor system. The monomer units 1 and 2 (0.2 M) and Pd catalyst (2 mol %) were dissolved in toluene and injected into one sample loop while the aqueous solution of Et₄NOH base was loaded in the second sample loop under anaerobic conditions (FIG. 1; Scheme c). For initial comparison between the batch and continuous reactions, the temperature of the tube reactor was set at 90° C. and the flow rate was adjusted to give a residence time of 1 h. Number average molecular mass (Mₑ) of 12000 g/mol and weight average molecular mass (M_{w}) of 39000 g/mol were obtained for the polymeric product by gel permeation chromatography GPC (Table 1, entry 3). This is significantly better than the mass distribution of the product of the batch reaction in the same reaction time period (Table 1, entry 1). By increasing the tube reactor temperature to 120° C., Mₙ of 23000 g/mol and M_{w} of 63000 g/mol were obtained (Table 1, entry 4). Decreasing the residence time to 30 min in the tube reactor also gave reasonable molecular weights (Table 1, entry 5).

Variations in other parameters, such as increase in temperature, adjusting monomer and base concentration, and catalyst loading generally led to less desirable molecular weights. An additional parameter of interest is the viscosity of the polymer solution. From qualitative observations, the polymer solution viscosity is rather high when cooled to room temperature which can lead to reactor over-pressurisation in large scale reactions. High polymer solution viscosity can be avoided by diluting the polymer solution with organic solvent (toluene) in line before collection (FIG. 1; Scheme c). Finally, additional reagent streams and reactor coils can easily be attached to the setup to enable in-line end-capping or extension to produce block polymers.

TABLE 1
Reaction conditions^{a} and molecular mass data for Suzuki polycondensations
in batch and continuous modes

| | | | Temp. | Reaction | Mₙ^{c} | M_{w} | | Isolated |
|---|---|---|---|---|---|---|---|---|
| Entry | Polymer | Method | [° C.] | Time [h] | [g/mol] | [g/mol] | M_{w}/Mₙ | Yield |
| 1 | PFO | Batch | 90 | 1 | 2900 | 3400 | 1.2 | —^{d} |
| 2 | | Batch | 90 | 2 | 21000 | 71000 | 3.4 | 64%^{e} |
| 3 | | Continuous | 90 | 1 | 12000 | 39000 | 3.4 | 70% |
| 4 | | Continuous | 120 | 1 | 23000 | 63000 | 2.8 | 90% |
| 5 | | Continuous | 120 | 0.5 | 20000 | 62000 | 3.1 | 70% |
| 6 | PCDHTBT | Batch^{b} | 90 | 14 | 15000 | 25000 | 1.6 | 74%^{f} |
| 7 | | Continuous | 120 | 2 | 12000 | 23000 | 1.9 | 79% |

^{a}[monomer] = 0.2M in toluene, [base] = 1M (aq.) and Pd catalyst loading = 2 mol %;
^{b}[monomer] for this reaction = 0.1M;
^{c}Molecular mass data was obtained by GPC;
^{d}This is an intermediate sample to determine molecular weight distribution;
^{e}Isolated yield of polymer after reaction for 24 h;
^{f}Isolated yield of polymer after reaction for 72 h.

### Suzuki Polycondensation for the Synthesis of High Performance Carbazole-Based Polymers

With high performance organic photovoltaic materials in mind, the carbazole polymer, PCDTBT [Park, S. H.; Roy, A.; Beaupre, S.; Cho, S.; Coates, N.; Moon, J. S.; Moses, D.; Leclerc, M.; Lee, K.; Heeger, A. J. Nat. Photon. 2009, 3, 297-303] was targeted for continuous synthesis. The reported synthesis of PCDTBT involves the Suzuki polycondensation of thienylbenzothiadiazole derivative 3a and the carbazole boronic acid pinacol ester derivative 4 in the presence of Pd catalyst, Et₄NOH base and toluene (FIG. 1; Scheme b) [Blouin, N.; Michaud, A.; Leclerc, M. Adv. Mater. 2007, 19, 2295-2300]. Unfortunately, the solubility of monomer 3a at 25° C. in organic solvents is far lower than the concentration commonly used for Suzuki polycondensations. Continuous reactions may be sensitive to reactant solubility and preferably require fully dissolved reactants to ensure accurate reaction stoichiometry and avoid reactor blockage. Monomer 3b was used as a soluble alternative to monomer 3a. The Suzuki polycondensation of monomers 3b and 4 gave polymer PCDHTBT [Kim, J.; Kwon, Y. S.; Shin, W. S.; Moon, S. J.; Park, T. Macromolecules 2011, 44, 1909-1919]. Following the continuous synthesis of PFO above, PCDHTBT was obtained by Suzuki polycondensation giving comparable molecular mass distributions to the batch reaction in much reduced reaction times (Table 1, entries 6 and 7).

### Stille Polycondensation for the Synthesis of High Performance Thiophene-Based Polymers

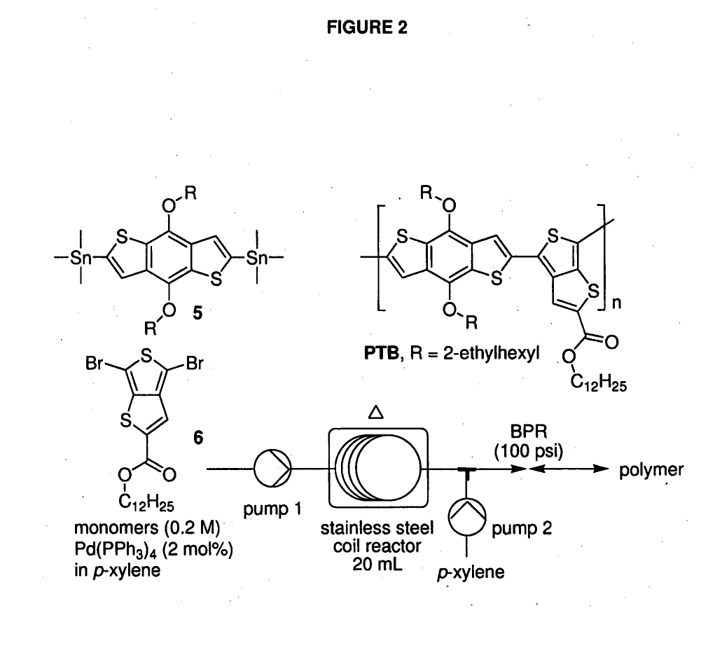

Stille polycondensation is often the method of choice for the synthesis of thiophene containing conjugated polymers. A number of high performance conjugated polymers for OPV applications have been synthesised using Stille coupling [Liang, Y. Y.;' Feng, D. Q.; Wu, Y.; Tsai, S. T.; Li, G.; Ray, C.; Yu, L. P. J. Am. Chem. Soc. 2009, 131, 7792-7799; Coffin, R. C.; Peet, J.; Rogers, J.; Bazan, G. C. Nat. Chem. 2009, 1, 657-661]. It has been shown that Stille polycondensations perform extremely well under microwave heating with good molecular weights achieved after 40 min at 170° C. [Coffin, R. C.; Peet, J.; Rogers, J.; Bazan, G. C. Nat. Chem. 2009, 1, 657-661]. Continuous methods also enable superior heat transfer and superheating under pressure. The alternating thieno[3,4-b]thiophene and benzodithiophene polymer, PTB, is a useful material as the OPV performance of close to 8% has been reported for some derivatives [Chen, H.-Y.; Hou, J.; Zhang, S.; Liang, Y.; Yang, G.; Yang, Y.; Yu, L.; Wu, Y.; Li, G. Nat. Photon. 2009, 3, 649-653]. Stille polycondensations were performed with monomers 5 and 6 and Pd(PPh₃)₄ dissolved in p-xylene under anhydrous and inert atmosphere conditions (FIG. 2). While further optimisation of continuous reaction parameters can lead to better control of polymer molecular weight distribution, there is no doubt that the continuous method is superior to the conventionally heated batch reaction and compares favourably with the microwave heated batch reaction (Table 2, entries 1-4).

TABLE 2
Reaction conditions and molecular mass data for PTB synthesised using Stille
polycondensation^{a} (entries 1-4) and MEH-PPV synthesised using the Gilch
method^{b} (entries 5-7) in batch and continuous modes.

| | | | Temp. | Reaction | Mₙ^{c} | M_{w} | | Isolated |
|---|---|---|---|---|---|---|---|---|
| Entry | Polymer | Method | [° C.] | Time [h] | [g/mol] | [g/mol] | M_{w}/Mₙ | Yield |
| 1 | PTB | Batch | 130 | 1 | 800 | 1000 | 1.2 | — |
| 2 | | Batch | 130 | 14 | 15000 | 28000 | 1.9 | 89% |
| 3 | | Batch (MW)^{d} | 170 | 1 | 16000 | 34000 | 2.1 | 62% |
| 4 | | Continuous | 170 | 1 | 17000 | 29000 | 1.7 | 75% |
| 5 | MEH-PPV | Batch | 25 | 5 | 70000 | 200000 | 2.8 | 77% |
| 6 | | Batch (initiator)^{e} | 25 | 5 | 69000 | 121000 | 1.7 | 82% |
| 7 | | Continuous | 25 | 0.5 | 55000 | 90000 | 1.6 | 72% |
| | | (initiator)^{e} | | | | | | |

^{a}Stille reaction: [monomer] = 0.2M, 2 mol % Pd catalyst in p-xylene;
^{b}Gilch reaction: [monomer] = 0.08M, [base] = 0.4M in THF;
^{c}Molecular mass data was obtained by GPC;
^{d}MW = microwave heating;
^{e}0.5 mol % 4-methoxyphenol.

### Synthesis of poly(phenylenevinylene) via the Gilch Route

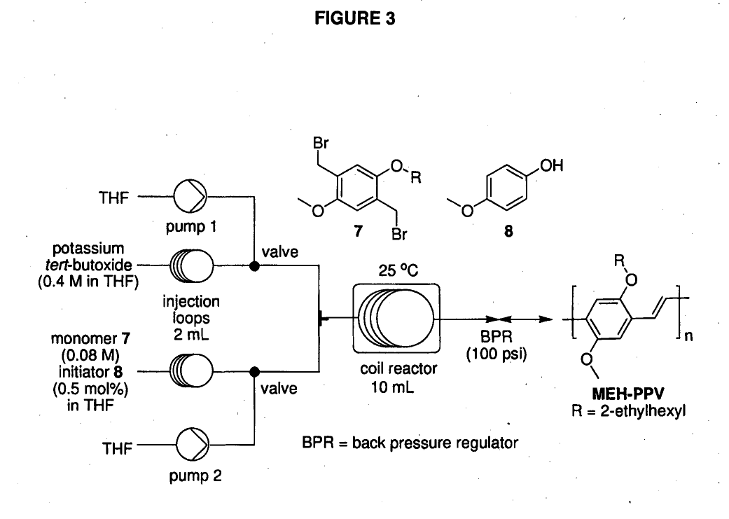

Solution processable poly(phenylenevinylene), MEH-PPV, has been used as the active material in both OLED and OPV devices. While there are many methods to synthesise PPV materials, perhaps the most convenient is the Gilch route involving α,α′-dihalo-p-xylenes and a strong base. Previous studies of MEH-PPV synthesis showed that reagent addition control is essential to achieve desired polymer mass distributions [Neef, C. J.; Ferraris, J. P. Macromolecules 2000, 33, 2311-2314; Schwalm, T.; Wiesecke, J.; Immel, S.; Rehahn, M. Macromolecules 2007, 40, 8842-8854]. This should translate well to the continuous process as precise addition of reagents can be easily achieved. To test the batch reaction, MEH-PPV was prepared by the slow addition (20 mL/h) of the α,α′-dibromo-p-xylene monomer 7 (0.08 M in THF) to a stirring solution of potassium Cert-butoxide (0.4 M in THF) under inert atmosphere. Viscosity increased rapidly and the reaction was allowed to stir for 5 h including the time taken for the addition of the monomer solution. It is important to note that using these concentrations of monomer and base, the viscosity reached such a high level that effective stirring of the solution was difficult. Mₙ of 70,000 g/mol and M_{w} of 200,000 g/mol were obtained for the MEH-PPV synthesised under these conditions (Table 2, entry 5). In order to avoid continuous reactor blockage, 4-methoxyphenol was used to control the molecular mass distribution [Neef, C. J.; Ferraris, J. P. Macromolecules 2000, 33, 2311-2314]. In the batch test reaction, 0.5 mol % of 4-methoxyphenol reduced the M_{w} to 121,000 g/mol with noticeably lower viscosity (Table 2, entry 6). The continuous synthesis of MEH-PPV was achieved by delivering the monomer and initiator in one channel and the base in the other channel (FIG. 3). With a residence time of 30 min in the tube reactor, Mₙ of 55,000 g/mol and M_{w} of 90,000 g/mol were measured for the polymeric product. This molecular mass distribution compares favourably to the batch process where the reaction time was 5 h (Table 2).

### Synthesis of Head-to-Tail poly(3-hexylthiophene) HT-P3HT via Grignard Metathesis Polymerisation

The preparation of head-to-tail poly(3-hexylthiophene) HT-P3HT via Grignard metathesis polymerization was performed by two methods.

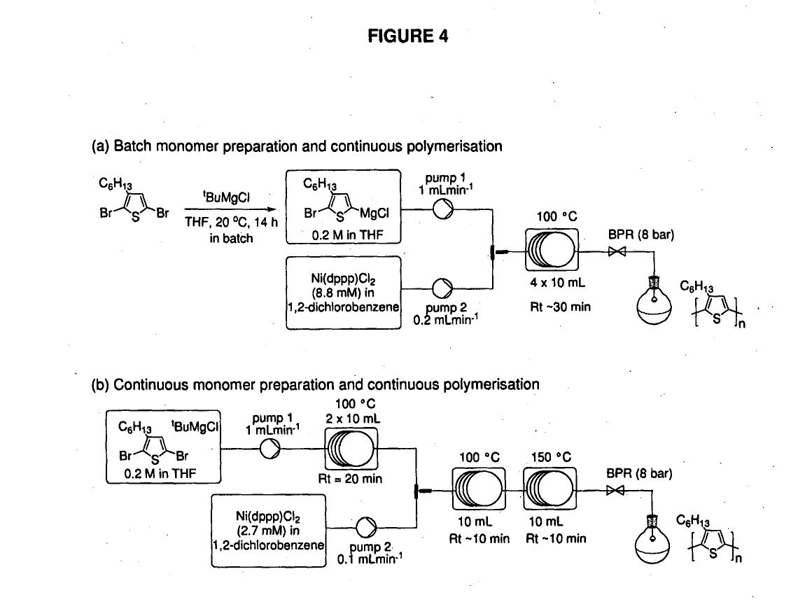

In the first method (FIG. 4(a)) a stock solution of Grignard monomer (5-bromo-4-hexylthiophenyl)magnesium chloride was prepared from t-butylmagnesium chloride and 2,5-dibromo-3-hexylthiophene via a batch process. This stock solution and a stock solution of Ni(dppp)Cl₂ were pumped into the coil reactor. The variation of the concentration of the thiophene monomer and flow rate of the catalyst solution afforded four different monomer to initiator ratios (0.9 mol %, 1.7 mol %, 2.9 mol %, 5.8 mol %, see Table 3). Table 3 also collects the results of molecular weight analyses of the formed polymers. Narrow polydispersity polymers of reasonable molecular weight were isolated.

TABLE 3
Gel permeation chromatography results*

| Entry | mol % | Mn (g/mol) | Mw (g/mol) | PDI |
|---|---|---|---|---|
| 1 | 0.9 | 13000 | 24900 | 1.9 |
| 2 | 1.7 | 9400 | 18400 | 1.9 |
| 3 | 2.9 | 5900 | 11700 | 2 |

*Solvent: toluene.
Detection: refractive index

In the second method (FIG. 4(b)) the Grignard monomer itself was generated via a continuous process and then subsequently reacted with catalyst in a further continuous process step. Accordingly, a stock solution containing 2,5-dibromo-3-hexylthiophene and t-butylmagnesium chloride was pumped into the preheated coil reactor resulting in a 20 min residence time. The product solution was then mixed with a second stream containing the catalyst Ni(dppp)C1₂. The mixture was then fed into a series of two reactors which were preheated at 100° C. and 150° C., respectively.

The inner reactor volume, the flow rates of monomer and catalyst stream, as well as the concentration of the later were varied to adjust the monomer to initiator ratio.

Table 4 collects the results of molecular weight analyses of the formed polymers at three different catalyst levels. It is noted that narrow polydispersity polymers of high molecular weight resulted.

TABLE 4
Gel permeation chromatography results*

| Entry | mol % | Mn (g/mol) | Mw (g/mol) | PDI |
|---|---|---|---|---|
| 1 | 0.1 | 27000 | 41000 | 1.5 |
| 2 | 0.28 | 20000 | 40000 | 2 |
| 3 | 1 | 8000 | 15000 | 1.9 |

*Solvent: toluene.
Detection: refractive index

These results demonstrate that monomers may be advantageously prepared in a continuous fashion and, further, the so formed monomer streams may be integrated into a further continuous polymerization reaction. The ability to integrate such process steps is clearly beneficial in delivering reproducible and efficient manufacture of conjugated polymers.

It will be apparent to the skilled artisan that the possible applications of the continuous processes of the present invention extend well beyond those specific embodiments hereinbefore described. These applications include a wide range of chemistries.

### EXAMPLES

The following examples demonstrate the efficacy of the continuous process of the present invention in the preparation of several conjugated polymers

### Experimental Procedures for Examples

The continuous experiments were conducted using a Vapourtec R2₊R4 unit (http://www.vapourtec.co.uk/). All solutions were degassed and reactions were performed under anaerobic conditions. Perfluoroalkoxy PFA (10 mL internal volume) or stainless steel (10 mL internal volume) tubing material was used in the reactor setups. The Vapourtec R4-pumping module equipped with manual loaded sample loops was used. The reactants were channeled into the tube reactor by pumping solvent from a reservoir. Residence times in the reactor coils were defined by the flow rate and the volume of the reactor. As the Stille reaction and the synthesis of MEH-PPV via the Gilch route require anhydrous conditions, the continuous reactor system was thoroughly dried by first flushing with anhydrous methanol followed by dried acetone before refilling with anhydrous reaction solvent.

¹H and ¹³C NMR measurements were and carried out from CDCl₃ solutions on a 500 MHz instrument. Gel permeation chromatography (GPC) data was obtained using a Viscotek GPC Max VE2001 solvent/sample module equipped with a Viscotek VE3580 refractive index detector. Toluene was used as the eluent with a 200 μl sample volume injection. Samples were passed through three 30 cm, PL gel (5 μm) mixed C columns and one 30 cm, PL gel (3 μm) mixed E column at 0.6 mL/min. Molecular mass distributions were calculated relative to narrow polystyrene reference standards.

### Synthetic Procedures

### Synthesis of poly(9,9-dioctylfluorene) PFO

2,7-Dibromo-9,9-dioctylfluorene (2.74 g, 5 mmol), 9,9-dioctylfluorene-2,7-bis(boronic acid pinacol ester) (3.21 g, 5 mmol) and tetrakis(triphenylphosphine)palladium(0) (115 mg, 2 mol %) were dissolved in toluene (25 mL). The solution was degassed by bubbling with nitrogen for 15 min and this was used as the stock monomer solution for both batch and continuous experiments. The base solution of Et₄NOH (25 mL, 1 M, aq.) was also degassed thoroughly and used for both batch and continuous reactions. More stock solutions were prepared as required.

### Comparative example 1

Batch reaction: The monomer stock solution (5 mL) and aqueous base solution (5 mL) were added to a Schlenk tube and heated at 90° C. Samples were taken from the reaction mixture at specific reaction times of 0.5, 1, 1.5, 2, 3, 4, 5 and 24 h and subjected to GPC analysis. After 24 h, the reaction was allowed to cool and the product was precipitated in MeOH. The residue was redissolved in toluene and filtered through a plug of silica followed by re-precipitation in MeOH. A pale yellow amorphous solid (250 mg, 64% yield) was collected by filtration and dried under vacuum.

¹H-NMR (CDCl₃, 500 MHz) δ ppm: 0.83 (t, J7 Hz, —CH₃), 1.1-1.3 (br m, —CH₂—), 2.14 (br m, —CH₂—), 7.70 (br m, ArH), 7.85 (br m, ArH). GPC data: Mₙ=29000; M_{w}=81000; M_{w}/Mₙ=2.8.

### Inventive Example 1

Continuous reactions: For each continuous reaction run, monomer stock solution (2 mL) and aqueous base solution (2 mL) were injected into the sample loops. Using the 10 mL PFA coil reactor unit, retention time of approximately 1 h was achieved at flow rates of 0.08 mL/min for each of the pump channels. The temperature of the coil reactor was adjusted on the Vapourtec R4 heating unit as required. Upon collection of the polymeric products, the same work-up procedure was used as the batch reaction above before GPC analysis. The NMR and GPC data for the continuous reaction performed at 120° C. for 1 h are given below.

¹H-NMR (CDCl₃, 500 MHz) δ ppm: 0.86 (t, J7 Hz, —CH₃), 1.1-1.3 (br m, —CH₂—), 2.17 (br m, —CH₂—), 7.72 (br m, ArH), 7.87 (br m, ArH). ¹³C-NMR (CDCl₃, 500 MHz) δ ppm: 14.1, 22.6, 23.9, 29.2, 30.1, 31.8, 40.4, 55.4, 120.0, 121.5, 126.2, 127.2, 128.8, 140.0, 140.5, 151.8. GPC data: Mₙ=23000; M_{w}=63000; M_{w}/Mₙ=2.8.

### Synthesis of Polymer PCDHTBT

### Comparative Example 2

Batch reaction: 9-(Heptadecan-9-yl)-2,7-bis(4,4,5,5-tetramethyl-1,3,2-dioxaborolan-2-yl)-9H-carbazole (132 mg, 0.2 mmol), 4,7-bis(5-bromo-4-hexylthieny-2-yl)-2,1,3-benzothiadiazole (126 mg, 0.2 mmol) and tetrakis(triphenylphosphine)palladium(0) (5 mg, 2 mol %) were dissolved in toluene (2 mL). The solution was degassed by bubbling with nitrogen for 15 min and a degassed solution of Et₄NOH (2 mL, 1 M, aq.) was added. The reaction was heated at 90° C. and monitored via GPC after 14 h and 36 h. After 72 h the polymer was end-caped with phenyl boronic acid (9 mg, 0.07 mmol) and bromobenzene (0.6 mL, 5 mmol). The reaction was allowed to cool and the product was precipitated in MeOH. The residue was purified by Soxhlet extraction with acetone and petroleum spirits 40-60° C. The remaining solid was extracted with CHCl₃ and the product was precipitated with methanol. A dark red amorphous solid (130 mg, 74% yield) was collected by filtration and dried under vacuum.

¹H-NMR (CDCl₃, 500 MHz) δ ppm: 0.82 (t, J 7.1 Hz, —CH₃), 0.89 (br m, —CH₃), 1.1-1.25 (br m, —CH₂—), 1.26-1.35 (br m, —CH₂—), 1.43 (br s, —CH₂—), 1.80 (br m, 2.00 (br m, —CH₂—), 2.36 (br m, —CH₂—), 2.88 (br s, —CH₂—), 4.64 (br m, —CH—), 7.43-7.47 (br m, ArH), 7.59 (br s, ArH), 7.76 (br s, ArH), 7.93 (br s, ArH), 7.14-7.20 (br m, ArH). GPC data: Mₙ=19000; M_{w}=39000; M_{w}/Mₙ=2.1.

### Inventive Example 2

Continuous reactions: A stock solution containing the Pd-catalyst (2 mol %), the carbazole- and benzothiadiazole monomers (1 mL, 0.2 M) and the aqueous base solution (1 mL) were degassed and filtered prior injection into the sample loops. Using the PFA coil reactor units (2×10 mL), retention time of approximately 2 h was achieved at flow rates of 0.08 mL/min for each of the pump channels. The temperature of the coil reactor was set at 120° C. on the Vapourtec R4 heating unit. Following the work-up described for the batch reaction, a dark red polymer (70 mg, 79%) was obtained.

¹H-NMR (CDCl₃, 500 MHz) δ ppm: 0.82 (m, —CH₃), 0.90 (br m, —CH₃), 1.23-1.18 (br m, —CH₂—), 1.33-1.27 (br m, —CH₂—),1.44 (br s), 1.80 (br m, —CH₂—), 2.00 (br m, —CH₂—), 2.38 (br m, —CH₂—), 2.89 (br s, —CH₂—), 4.65 (br m, —CH—), 7.48-7.44 (br m, ArH), 7.59 (br s, ArH), 7.76 (br s, ArH), 7.94 (br m, ArH), 8.21-8.15 (br m, ArH). ¹³C-NMR (CDCl₃, 500 MHz) δ ppm: 14.0, 14.1, 22.6, 22.7, 27.0, 29.2, 29.4, 29.5, 31.3, 31.8., 33.9, 56.7, 109.6, 112.1, 120.2, 120.6, 121.7, 123.11, 125.3, 125.8, 130.6, 131.5, 132.0, 137.3, 139.2, 139.8, 140.9, 142.6, 152.8. GPC data: Mₙ=12000; M_{w}=23000; M_{w}/Mₙ=1.9.

### Synthesis of Polymer PTB

### Comparative Example 3

Batch reaction with conventional heating: 2,6-Bis(trimethyltin)-4,8-bis(2-ethylhexyloxy)benzo[1,2-b:4,5-b′]dithiophene (362 mg, 0.5 mmol) and dodecyl 4,6-dibromo-thieno[3,4-b]thiophene-2-carboxylate (240 mg, 0.5 mmol) were dissolved in p-xylene (2.35 mL). The solution was degassed by bubbling with nitrogen for 15 min and tetrakis(triphenylphosphine)-palladium(0) (12 mg, 2 mol %) was added. The reaction was heated at 130° C. and monitored via GPC after 1, 2, 3 and 4 h. After 14 h the mixture was allowed to cool, the product was precipitated in MeOH and washed twice with methanol and petroleum spirits. A black amorphous solid (334 mg, 89%) was collected by filtration and dried under vacuum.

¹H-NMR (CDCl₃, 500 MHz) δ ppm: 0.77-2.27 (br m, —CH₂—, CH₃), 3.6-4.7 (br m, O—CH₂—), 6.5-8.2 (br m, ArH). GPC data: Mₙ=15000; M_{w}=28000; M_{w}/Mₙ=1.9.

### Comparative Example 4

Batch reaction with microwave heating: 2,6-Bis(trimethyltin)-4,8-bis(2-ethylhexyloxy)-benzo[1,2-b:4,5-b′]dithiophene (309 mg, 0.4 mmol) and dodecyl 4,6-dibromo-thieno[3,4-b]thiophene-2-carboxylate (204 mg, 0.4 mmol) and tetrakis(triphenylphosphine)-palladium(0) (12 mg, 2.5 mol %) were placed in a microwave vial and sealed with a septum cap under inert atmosphere. Degassed and dried p-xylene (2 mL) was added and the reaction was heated in the microwave reactor (Biotage Initiator Sixty) at 120° C. for 5 min, 140° C. for 5 min and 170° C. for 40 min. The resulting polymeric product (200 mg, 62% yield) was isolated in the same fashion as the batch reaction with conventional heating above.

¹H-NMR (CDCl₃, 500 MHz) δ ppm: 0.73-2.3 (br m, CH₃, —CH₂—), 3.5-4.7 (br m, O—CH₂—), 6.7-8.1 (br m, ArH). GPC data: Mₙ=16000; M_{w}=34000; M_{w}/Mₙ=2.1.

### Inventive Example 3

Continuous reactions: A stock solution (1.65 mL, 0.2 M) containing 2,6-bis(trimethyltin)-4,8-bis(2-ethylhexyloxy)benzo[1,2-b:4,5-b′]dithiophene (255 mg, 0.33 mmol), dodecyl 4,6-dibromo-thieno[3,4-b]thiophene-2-carboxylate (171 mg, 0.33 mmol) and tetrakis(triphenylphosphine)-palladium(0) (8 mg, 2 mol %) were pumped into the stainless steel coil reactor units (2×10 mL). The temperature was set at 170° C. and retention time of approximately 1 h was achieved at a flow rate of 0.33 mL/min. The crude polymer solution was collected and the same work-up procedure was used as the batch reaction. A black polymer (197 mg, 75%) was isolated.

¹H-NMR (CDCl₃, 500 MHz) δ ppm: 0.8-2.14 (br m, —CH₂—, CH₃), 3.6-4.7 (br m, O—CH₂—), 6.5-8.1 (br m, ArH). ¹³C-NMR (CDCl₃, 500 MHz) δ ppm: 11.3, 14.1, 22.7, 23.2, 23.89, 26.0, 29.5, 29.8, 32.1, 40.6, 65.9, (aromatic signals are very broad with low S/N ratios). GPC data: Mₙ=17000; M_{w}=29000; M_{w}/Mₙ=1.7

### Synthesis of poly(1-methoxy-4-(2-ethylhexyloxy)-p-phenylenevinylene) MEH-PPV

### Comparative Example 5

Batch reaction: Potassium tert-butoxide (5 mL, 1 M) was added to anhydrous THF (20 mL). α,α′-Dibromo-2-methoxy-5-(2-ethylhexyloxy)xylene (0.5 g, 1.2 mmol) in anhydrous THF (5 mL) was added dropwise using a syringe pump at a rate of 20 mL/h. The reaction was allowed to stir for 5 h at 25° C. and the product was precipitated in MeOH. A red amorphous solid (0.25 g, 77% yield) was collected by filtration and dried under vacuum.

¹H-NMR (CDCl₃, 500 MHz) δ ppm: 0.92 (br m, —CH₃), 1.01 (br m, —CH₃), 1.37 (br m, —CH₂—), 1.54 (br m, —CH₂—), 1.83 (br m, —CH—), 3.9-4.1 (br m, —OCH₂— and —OCH₃), 7.20 (br m, vinyl-H), 7.4-7.5 (br m, ArH). GPC data: Mₙ=70000; M_{w}=200000; M_{w}/Mₙ=2.8.

### Comparative Example 6

Batch reaction with initiator: Potassium tert-butoxide (4 mL, 1 M) and 4-methoxyphenol (0.5 mg, 0.5 mol %) were added to anhydrous THF (6 mL). α,α′-Dibromo-2-methoxy-5-(2-ethylhexyloxy)xylene (0.34 g, 0.8 mmol) in anhydrous THF (10 mL) was added dropwise using a syringe pump at a rate of 20 mL/h. The reaction was allowed to stir for 5 h at 25° C. and the product was precipitated in MeOH. A red amorphous solid (0.17 g, 82% yield) was collected by filtration and dried under vacuum.

¹H-NMR (CDCl₃, 500 MHz) δ ppm: 0.92 (br m, —CH₃), 1.02 (br m, —CH₃), 1.37 (br m, —CH₂—), 1.5-1.7 (br m, —CH₂—), 1.83 (br m, —CH—), 3.9-4.1 (br m, —OCH₂— and —OCH₃), 7.20 (br m, vinyl-H), 7.4-7.5 (br m, ArH). GPC data: Mₙ=69000; M_{w}=121000; M_{w}/Mₙ=1.7.

### Inventive Example 4

Continuous reaction with initiator: The base solution was prepared by adding potassium tert-butoxide (4 mL, 1 M) and 4-methoxyphenol (0.5 mg, 0.5 mol %) to anhydrous THF (6 mL). The monomer solution was prepared by dissolving α,α′-dibromo-2-methoxy-5-(2-ethylhexyloxy)xylene (0.34 g, 0.8 mmol) in anhydrous THF (10 mL). The base and monomer solutions were injected into the sample loops and the reactants were pushed through the coil reactor at 25° C. The flow rate was adjusted -to give a retention time of 30 min in the 10 mL coil reactor. The polymeric product was collected and precipitated in MeOH. A red amorphous solid (0.15 g, 72% yield) was collected by filtration and dried under vacuum.

¹H-NMR (CDCl₃, 500 MHz) δ ppm: 0.92 (br m, —CH₃), 1.02 (br m, —CH₃), 1.37 (br m, —CH₂—), 1.5-1.7 (br m, —CH₂—), 1.83 (br m, —CH—), 3.9-4.1 (br m, —OCH₂— and —OCH₃), 7.20 (br m, vinyl-H), 7.4-7.5 (br m, ArH). ¹³C-NMR (CDCl₃, 500 MHz) δ ppm: 11.4, 14.1, 23.1, 24.3, 29.2, 30.9, 39.9, 56.1, 56.5, 71.3, 109.1, 110.1, 126.4, 127.3, 128.6, 129.7, 151.5. GPC data: Mₙ=55000; M_{w}=90000; M_{w}/Mₙ=1.6.

### Synthesis of head-to-tail poly(3-hexylthiophene) HT-P3HT

### Inventive Example 5

Batch Monomer Preparation and Continuous Polymerisation

Preparation of Grignard monomer stock solution [0.3M]: t-Butylmagnesium chloride was added dropwise to a solution of 2,5-dibromo-3-hexylthiophene (1.47 g, 4.5 mmol) in dry THF (9 mL) and the mixture was stirred overnight at room temperature. Full conversion to the mono-Grignard reagent was confirmed via ¹H-NMR from the quenching of a 0.3 mL aliquot in water and extraction with PE.

Polymerization: Stock solutions (0.2 M-0.06 M) containing (5-bromo-4-hexylthiophenyl)magnesium chloride and Ni(dppp)Cl₂ (8.8 mM) were pumped into the stainless steel coil reactor (4×10 mL, 100° C.) at 1 mL/min and 0.2-0.4 mL/min flow rate, respectively. The variation of the concentration of the thiophene monomer and flow rate of the catalyst solution afforded four different monomer to initiator ratios (0.9 mol %, 1.7 mol %, 2.9 mol %, 5.8 mol %, see table 3). The stream outlet was fitted with a 250 psi back pressure regulator. The mixtures were quenched and precipitated from 2N methanolic HCl, centrifuged and washed with the same solvent (×3).

¹H-NMR (CDCl₃, 500 MHz) δ ppm: 0.94 (s, 3H), 1.23-1.55 (m, 6H), 1.73 (s, 2H), 2.82 (s, 2H), 7.0 (s, 1H). ¹³C-NMR (CDCl₃, 125 MHz) δ ppm: 14.11, 22.65, 29.26, 30.51, 31.70, 128.59, 130.49, 133.71, 139.88.

### Inventive Example 6

Continuous Monomer Preparation and Continuous Polymerisation

A stock solution of monomer was prepared by mixing 2,5-dibromo-3-hexylthiophene (0.2 M in THF) and t-butylmagnesium chloride (1 equiv.) in a flask. This solution was pumped into the preheated PFA coil reactor (Vᵢₙₙₑᵣ=2×10 mL, 100° C.) at 1mL/min flow rate, resulting in 20 min residence time. The solution was then mixed with a second stream containing Ni(dppp)Cl₂ (2.7 mM) at 0.1mL/min to give a 0.1mol % catalyst content. The mixture was fed into a series of two reactors (preheated at 100° C. and 150° C., respectively). The inner pressure of the system was adjusted to give a continuous steady flow using a 250 psi back pressure regulator located at the outlet of the system. The mixture was quenched directly into methanol, centrifuged and washed with methanol three times.

The inner reactor volume, the flow rates of monomer and catalyst stream, as well as the concentration of the later were varied to adjust the monomer to initiator ratio.

¹H-NMR (CDCl₃, 500 MHz) δ ppm: 0.94 (s, 3H), 1.23-1.55 (m, 6H), 1.73 (s, 2H), 2.82 (s, 2H), 7.0 (s, 1H). ¹³C-NMR (CDCl₃, 125 MHz) δ ppm: 14.11, 22.65, 29.26, 30.51, 31.70, 128.59, 130.49, 133.71, 139.88.

1. A process for the synthesis of conjugated polymers wherein the process comprises one or more continuous process steps.

2. The process according to claim 1 wherein the process comprises one or more monomer synthesis steps followed by one or more polymer synthesis steps.

3. The process according to claim 1 wherein the one or more polymer synthesis steps comprises a chemical reaction selected from the group consisting of palladium-catalysed polycondensation, Buchwald-Hartwig amination, ring opening metathesis polymerisation, Yamamoto polycondensation, Gilch polymerisation, Wittig polycondensation, Grignard metathesis polymerisation and combinations thereof.

4. The process according to claim 3 wherein the palladium-catalysed polycondensation is selected from the group consisting of Suzuki, Stille, Sonogashira and Heck reactions and combinations thereof.

5. The process according to claim 2 wherein the one or more monomer synthesis steps comprises a chemical reaction selected from the group consisting of halogenation, lithiation, metallation/transmetallation, borylation, formylation, alkylation and combinations thereof.

6. The process according to claim 1 wherein the one or more process steps are performed in a mixture of solvents

7. The process according to claim 6 wherein the one or more process steps are performed under biphasic conditions.

8. The process according claim 1 wherein one or more process steps are catalysed by one or more homogeneous and/or heterogeneous catalysts.

9. The process according to claim 8 wherein the one or more heterogeneous catalysts are present in one or more fixed beds.

10. The process according to claim 1 wherein one or more monomers, catalysts or other reagents are fed to the one or more process steps from separate storage vessels.

11. The process according to claims 1 wherein one or more monomers, catalysts or other reagents are pre-mixed before entering a reaction zone.

12. The process according to claim 1 wherein one or more monomers, catalysts or other reagents are added in separate streams to a reaction zone.

13. The process according to claim 1 wherein one or more process steps is performed in one or more tubular reactors, one or more continuous stirred tank reactors or combinations thereof.

14. The process according to claim 1 wherein one or more of the process steps is automated through a process control system.

15. The process according to claim 1 further comprising one or more continuous process steps wherein the so-formed conjugated polymer is end-capped.

16. The process according to claim 1 further comprising one or more continuous process steps wherein the so-formed conjugated polymer is chain extended to form a block polymer.

17. The process according to claim 16 wherein the block polymer is a block copolymer.

18. A conjugated polymer synthesised by the process according to claim 1.

19. The conjugated polymer according to claim 18 wherein the polymer is selected from the group consisting of poly(fluorene), poly(dibenzosilole), poly(dibenzogermole), poly(dibenzophosphole oxide), poly(phenylene), poly(pyrene), poly(azulene), poly(naphthalene), poly(pyrole), poly(carbazole), poly(indole), poly(azepine), poly(aniline), poly(thiophene), poly(3,4-ethylenedioxythiophene), poly(cyclopentadithiophene), poly(dithienosilole), poly(dithlenogermole), poly(dithienophosphole oxide), poly(benzodithiophene), poly(benzotriazole), poly(thiazole), polyp-phenylene sulphide), poly(acetylene) and poly(p-phenylenevinylene).

20. (canceled)

21. A hetero junction device comprising one or more conjugated polymers according to claim 18.
